(19) United States
(12) Patent Application Publication
(10) Pub. No.: US 2013/0153999 A1
(43) Pub. Date: Jun. 20, 2013

(54) TRENCH GATE MOSFET DEVICE

(71) Applicants: Lei Zhang, Chengdu (CN); Donald Disney, Chengdu (CN); Tiesheng Li, Chengdu (CN); Rongyao Ma, Chengdu (CN)

(72) Inventors: Lei Zhang, Chengdu (CN); Donald Disney, Chengdu (CN); Tiesheng Li, Chengdu (CN); Rongyao Ma, Chengdu (CN)

(21) Appl. No.: 13/722,863

(22) Filed: Dec. 20, 2012

(30) Foreign Application Priority Data
Dec. 20, 2011 (CN) 201110428855.0

(51) Int. Cl. H01L 29/78; H01L 27/088

(52) U.S. Cl. CPC H01L 29/7813; H01L 27/088
USPC 257/334; 257/330

(57) ABSTRACT

A trench gate MOSFET device has a drain region, a drift region, a trench gate having a gate electrode and a poly-silicon region, a super junction pillar juxtaposing the trench gate, a body region and a source region. By the interaction among the trench gate, the drift region and the super junction pillar, the break down voltage of the trench gate MOSFET device may be relatively high while the on-state resistance of the trench gate MOSFET device may be maintained relatively small.

### CROSS-REFERENCE TO RELATED APPLICATION(S)

This application claims the benefit of CN application No. 201110428855.0, filed on Dec. 20, 2011, and incorporated herein by reference.

### TECHNICAL FIELD

The present invention generally relates to semiconductor device, and more particularly but not exclusively relates to trench gate metal oxide semiconductor field effect transistor (trench gate MOSFET) device.

### BACKGROUND

Currently, power devices are widely applied in the area of switch-mode power supply, vehicle electronics, industry control and etc. Since the trench gate MOSFET has an increased total channel width within per unit area of chip, it may reduce the on-state resistance of the device and thus is preferred. However, for conventional trench gate MOSFET device, improving the break down voltage would contradict decreasing the on-state resistance, which makes it hard to improve the break down voltage and to reduce the on-state resistance at the same time. Therefore, when this device is utilized in high voltage occasions, the energy consumption is relatively high.

### SUMMARY

One embodiment of the present invention discloses a trench gate metal oxide semiconductor field effect transistor (trench gate MOSFET) device comprising: a substrate, having a first conductivity type; an epitaxy layer, formed on the substrate and having a top surface, wherein the doping concentration of the epitaxy layer is lower than the substrate; a trench, extending downward from the top surface of the epitaxy layer, wherein the depth of the trench is smaller than the thickness of the epitaxy layer; an insulation layer, filled into the trench and covering an internal surface of the trench; a poly-silicon region, formed inside the trench and enclosed by the insulation layer; a gate electrode, formed in the trench, the gate electrode extending downward from the top surface of the epitaxy, and the gate electrode enclosed by the insulation layer; a pillar structure, formed in the epitaxy layer and having a second conductivity type; a body region, formed in the epitaxy layer and having a second conductivity type, wherein the body region contacts a side wall of the trench and a top surface of the pillar structure, and wherein the depth of the body region is smaller than the thickness of the gate electrodes, and further wherein the doping concentration of the body region is higher than the doping concentration of the pillar structure; and a source contact region, formed on the body region and contacting the sidewall of the trench, wherein the doping concentration of the source contact region is higher than the doping concentration of the epitaxy layer.

By the interaction among the trench gate, the drift region and the super junction pillar, the break down voltage of the trench gate MOSFET device may be relatively high while the on-state resistance of the trench gate MOSFET device may be maintained relatively small.

### BRIEF DESCRIPTION OF THE DRAWINGS

Non-limiting and non-exhaustive embodiments are described with reference to the following drawings. The drawings are only for illustration purpose and are not necessarily drawn to scale.

FIG. 1 illustrates a schematic cross-sectional structure diagram of an N-channel trench gate MOSFET device 10 according to an embodiment of the present invention.

FIG. 2 illustrates a schematic cross-sectional diagram of another N-channel trench gate MOSFET 20 according to another embodiment of the present invention.

FIG. 3 illustrates a schematic cross-sectional diagram of yet another N-channel trench gate MOSFET 30 according to yet another embodiment of the present invention.

FIG. 4 illustrates a schematic cross-sectional diagram of a trench gate MOSFET 40 according to an embodiment of the present invention.

FIG. 5 illustrates a schematic cross-sectional diagram of an N-channel trench gate MOSFET 50 according to an embodiment of the present invention.

FIG. 6 illustrates a schematic cross-sectional diagram of an N-channel trench gate MOSFET device with a plurality of duplicated units according to an embodiment of the present invention

The use of the same reference label in different drawings indicates the same or like components.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

To alleviate the contradiction between the break down voltage BV and the on-state resistance Rds(on), the embodiments of the present invention propose a trench gate MOSFET device comprising a super junction structure and a capacitive depletion structure. By means of this type trench gate MOSFET, the performance of the device may be improved.

The following descriptions for certain embodiments of the present invention will take an N-type trench gate MOSFET as an exemplary for illustration. However, one with ordinary skill in relevant art should understand that in other embodiments, P-type trench gate MOSFET may also be applied properly.

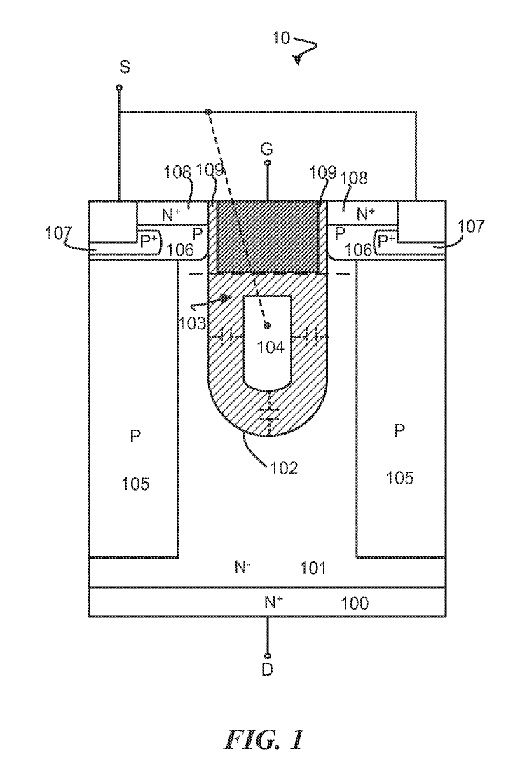

FIG. 1 illustrates a schematic cross-sectional structure diagram of an N-channel trench gate MOSFET device 10 according to an embodiment of the present invention. As shown in FIG. 1, the N-channel trench gate MOSFET 10 comprises an N+ substrate 100 and an N− epitaxy layer 101 formed thereon. In one embodiment, the N+ substrate 100 may serve as a drain region of the trench gate MOSFET 10 on which a drain electrode D may be contacted from. MOSFET device 10, while the N− epitaxy may serve as a drift region of the trench gate MOSFET device 10. The doping concentration of the N− epitaxy layer 101 is lower than that of the N+ substrate 100. The N-channel trench gate MOSFET 10 further comprises a trench 102, vertically extending downward from a top surface of the N− epitaxy layer 101. The depth of the trench 102 is smaller than the thickness of the epitaxy layer 101 which means the trench 102 does not contact the surface of the N+ substrate 100. An insulation layer is filled into the trench 102 and covers internal surface of the trench 102. The insulation layer comprises a first insulation layer 103 and a second insulation layer 109, which respectively cover a lower part internal surface of the trench 102 and an upper part internal surface of the trench 102, wherein the thickness of the first insulation layer 103 is larger than the thickness of the second insulation layer 109. The trench 102 further comprises a poly-silicon region 104, wherein the poly-silicon region 104 is totally enclosed by the first insulation layer 103. A gate electrode G vertically extends downward from a top surface of the trench 102 to the upside of the poly-silicon region 104. The gate electrode G is enclosed by the insulation layer, wherein a sidewall of the gate electrode G is covered by the second insulation layer 109 and wherein a bottom side of the gate electrode G is covered by the first insulation layer 103. The trench 102, the insulation layer, the poly-silicon region 104 and the gate electrode G together comprise a trench gate structure. The N-channel trench gate MOSFET 10 further comprises a P-type pillar structure 105 as a super junction pillar, formed inside the N− epitaxy layer 101, juxtaposing the trench 102, wherein the pillar structure 105 is enclosed by the N− epitaxy layer 101. A P-type body region 106 contacts the epitaxy layer 101 and a top surface of the pillar structure 105 with a bottom surface. A side wall of the P-type body region 106 contacts the side wall of the trench 102. Wherein, the depth of the P-type body region 106 is smaller than the depth of gate electrode G, and the doping concentration of the P-type body region 106 is higher than that of P-type pillar structure 105. A P+ region 107 is formed inside the P-type body region 106 and does not contact the top surface of the body region 106. The doping concentration of the P+ region is higher than the body region 106. Inside the body region 106, an N+ region 108 is further formed above the P+ region 107 as a source contact region and exposed at the surface of the epitaxy layer 101. The source contact region 108 further contacts the side wall of the trench 102. The doping concentration of the source contact region 108 is higher than N− epitaxy layer 101. A source electrode S is also formed inside the P-type body region 106. The source electrode S stretches from the top surface of the N− epitaxy layer 101 to contact the P+ region 107 and the source contact region 108.

For a conventional N-channel MOSFET device, when the device is in off state, a source S is connected to ground and a drain D is coupled to a positive voltage level. This positive voltage is undertaken by a PN junction formed by the P-type body region 106 and the N− epitaxy layer 101. Seen in FIG. 1, the N-channel trench gate MOSFET 10 according to the illustrated embodiment has a super junction structure formed by the P-type pillar structure 105. Because the doping concentration of P-type pillar structure 105 is lower than the doping concentration of P-type body region 106, the PN junction formed by P-type pillar structure 105 and N− epitaxy layer 101 may undertake a relative high voltage, and thereby the break-down voltage BV may be improved. While for the illustrated embodiment, as the epitaxy layer 101 may have a relative high doping concentration compared with conventional trench gate MOSFET, the on-state resistance Rds(on) may be reduced simultaneously.

Continuing with FIG. 1, the poly-silicon region 104, the first insulation layer 103 and the N− epitaxy layer 101 together comprise a capacitive depletion structure, i.e. a metal-insulator-semiconductor (MIS) capacitor structure, wherein the poly-silicon region 104 and the N− epitaxy layer 101 are two polar plates of the capacitor and wherein the first insulation layer 103 is a dielectric of the capacitor. In the illustrated embodiment, the poly-silicon region 104 is coupled to the source electrode S. When the drain electrode D is coupled to a positive voltage level and the source electrode S is connected to ground, a capacitive depletion area will be formed in the N− epitaxy layer 101. This capacitive depletion area interacts with the P-type body region 106, the N− epitaxy layer 101, and the PN junction formed by the P-type pillar structure 105 and the N− epitaxy layer 101, configured to expand the width of the depletion region in the trench gate MOSFET device, and thus to increase the break down voltage BV. Meanwhile, in the illustrated embodiment, the doping concentration of the N− epitaxy layer 101 may be relatively high and thus the on-state resistance Rds(on) of the device is reduced, especially for high voltage application. The parasitic capacitance formed by the drain electrode D, the source electrode S and the N− epitaxy layer 101 may also be relatively small due to the utilization of the poly-silicon region 104.

In one embodiment, by choosing proper doping concentrations and width values for the P-type body region 106, the P-type pillar structure 105 and the N− epitaxy layer 101, when the drain electrode D is coupled to a certain voltage, the portion of N− epitaxy layer 101 that is between the pillar structure 105 and the poly-silicon region 104 may be completely depleted, and resulting in achieving a larger break down voltage BV.

In the illustrated embodiment, the poly-silicon region 104 is coupled to the source electrode S and the ground. However, in another embodiment, the poly-silicon region 104 may be coupled to a voltage level lower than the voltage level on the drain region. In yet another embodiment, the MOSFET device may be a P-channel trench gate MOSFET device and the poly-silicon region may be coupled to a voltage level higher than the voltage level on the drain region.

In embodiment shown in FIG. 1, P-type body region 106, P+ region 107, N+ source contact region 108 and the metal source electrode S together comprise an active area. However, one with ordinary skill in relevant art should understand that in other embodiments, the shapes, structures or relative positions of these active area elements (P-type body region 106, P+ region 107, N+ source contact region 108 and source electrode S) may be varied. In certain embodiments, the P+ region 107 may be omitted.

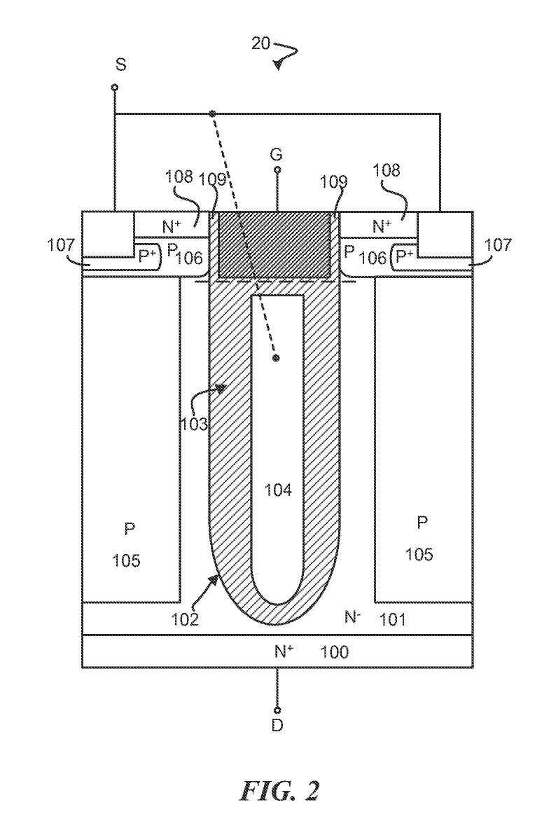

FIG. 2 illustrates a schematic cross-sectional diagram of another N-channel trench gate MOSFET 20 according to another embodiment of the present invention. As shown in FIG. 2, compared with the N-channel trench gate MOSFET shown in FIG. 1, the P-type pillar structure 105, the trench 102 and the poly-silicon region 104 stretch into the N− epitaxy layer 101 and extend downward to a position that is near the substrate 100, configured to expand the depletion region along longitudinal direction and consequently to obtain a larger break down voltage BV.

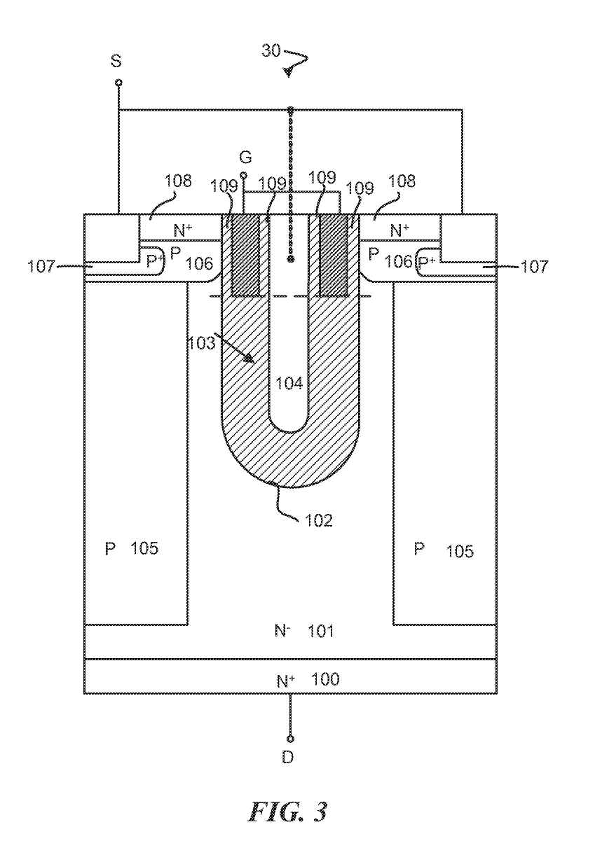

FIG. 3 illustrates a schematic cross-sectional diagram of another N-channel trench gate MOSFET 30 according to another embodiment of the present invention. Seen in FIG. 3, compared with the trench gate MOSFET 10, the poly-silicon region 104 and the gate electrode G are differently arranged. Specifically, the poly-silicon region 104 and the gate electrode G are horizontally arranged in the trench 102. In trench gate MOSFET 30, the first insulation layer 103 and the second insulation layer 109 respectively cover the lower part internal surface of trench 102 and the upper part internal surface of trench 102. The thickness of the first insulation layer 103 is larger than the second insulation layer 109. The trench 102 comprises poly-silicon region 104, and extends downward from the top surface of the N− epitaxy layer 101. The poly-silicon region 104 is enclosed by the insulation layer, wherein a lower part sidewall and a bottom surface of the poly-silicon region 104 are covered by the first insulation layer 103, and wherein an upper part sidewall of the poly-silicon region 104 is covered by the second insulation layer 109. The trench 102 further comprises the gate electrode G, extending downward from the top surface of the N− epitaxy layer 101. The gate electrode G is enclosed by the insulation layer, wherein the sidewall of the gate electrode G is covered by the first insulation layer 103 and wherein the bottom surface of the gate electrode G is covered by the second insulation layer 109.

One with ordinary skill in relevant art should understand that the trench gate MOSFET devices 10, 20 and 30 shown in FIG. 1-3 according to some embodiments of the present invention have some specific structures, shapes or arrangements for the poly-silicon region and the gate electrode in the trench. However, in other embodiments of the present invention, the poly-silicon region 104 and the gate electrode G may have different shapes, structures, and/or arrangements.

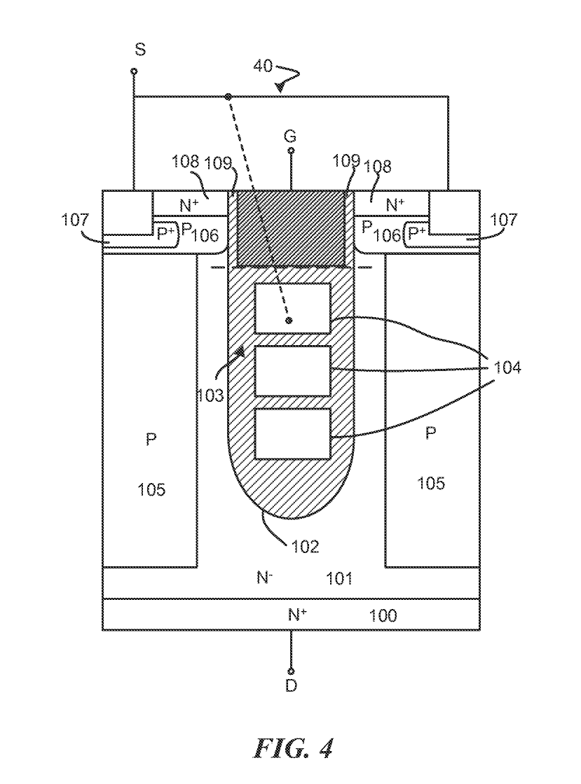

FIG. 4 illustrates a schematic cross-sectional diagram of another trench gate MOSFET 40 according another embodiment of the present invention. Compared with the trench gate MOSFET 10, the trench gate MOSFET 40 comprises a plurality of poly-silicon regions 104 which are separated from each other inside the trench 102. The poly-silicon regions 104 are enclosed by the first insulation layer 103 and are vertically arranged in the trench 102. Similar to the principle described above, the poly-silicon regions 104, the first insulation layer 103 and the N− epitaxy 101 together comprise a capacitor configured to generate a capacitive depletion region. This capacitive depletion region may interact with the P-type body region 106, N− epitaxy layer 101, and the PN junction formed by the P-type pillar structure 105 and N− epitaxy layer 101, configured to generate a wider depletion area under a certain drain voltage compared with conventional trench gate MOSFET. Thus the break down voltage BV may be improved.

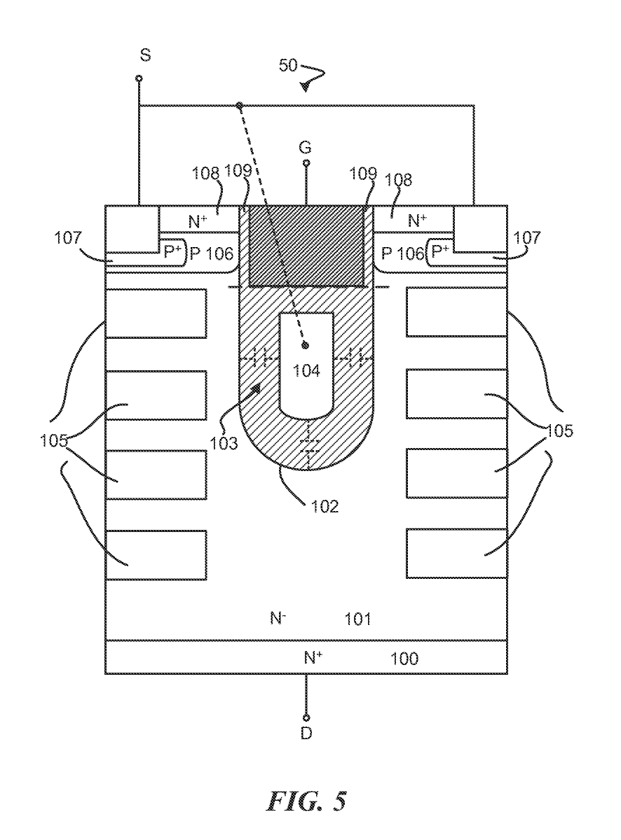

FIG. 5 illustrates a schematic cross-sectional diagram of an N-channel trench gate MOSFET 50 according to yet another embodiment of the present invention. Seen in FIG. 5, compared with trench gate MOSFET 10, the trench gate MOSFET 50 comprises a plurality of P-type pillar structures 105 which are separated from each other. The P-type pillar structures are enclosed by the N− epitaxy layer 101 and are vertically arranged in N− epitaxy layer 101, and form a plurality of PN junctions with the N− epitaxy layer 101 to undertake the applied voltage. Thus the break-down voltage BV may be improved compared with conventional N-channel trench gate MOSFET devices.

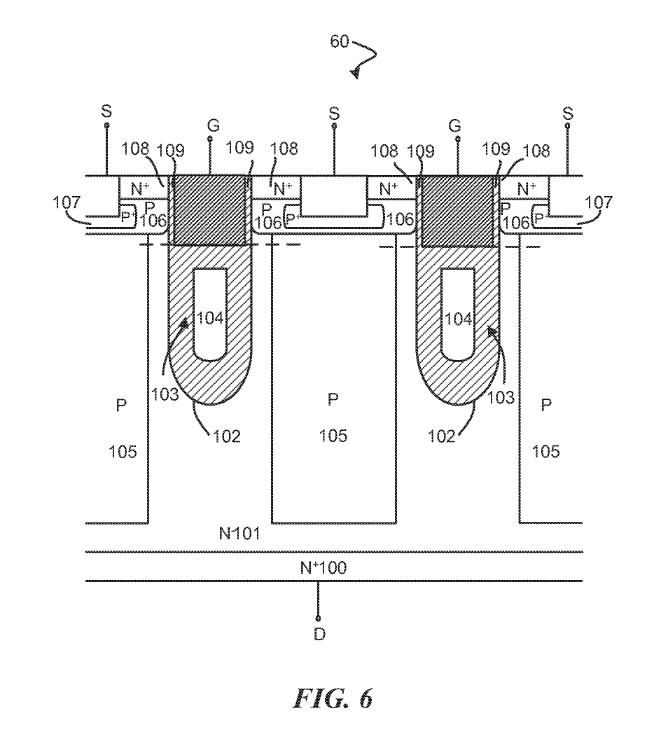

FIG. 6 illustrates a schematic cross-sectional diagram of an N-channel trench gate MOSFET device 60 according to an embodiment of the present invention. The trench gate MOSFET 60 comprises a plurality of duplicated trench gate MOSFET units, wherein each of the MOSFET unit may comprise the trench gate MOSFET shown in FIGS. 1-5 or any other suitable structures according to other embodiments of the present invention.

The above description and discussion about specific embodiments of the present invention is for purposes of illustration. However, one with ordinary skill in the relevant art should know that the invention is not limited by the specific examples disclosed herein. Variations and modifications can be made on the apparatus, methods and technical design described above. Accordingly, the invention should be viewed as limited solely by the scope and spirit of the appended claims.

I/We claim:

1. A trench gate MOSFET device, comprising:
a substrate, having a first conductivity type;
an epitaxy layer, formed on the substrate, the epitaxy layer having a top surface, wherein the epitaxy layer having the first conductivity type and the doping concentration of the epitaxy layer is lower than the doping concentration of the substrate;
a trench, extending downward from the top surface of the epitaxy layer, wherein the depth of the trench is smaller than the thickness of the epitaxy layer;
an insulation layer, filled into the trench, the insulation layer covering an internal surface of the trench;
a poly-silicon region, formed inside the trench and enclosed by the insulation layer;
a gate electrode, formed in the trench, the gate electrode extending downward from the top surface of the epitaxy, and the gate electrode enclosed by the insulation layer;
a pillar structure, formed in the epitaxy layer, the pillar structure having a second conductivity type;
a body region, formed in the epitaxy layer, the body region having the second conductivity type, wherein the body region contacts a side wall of the trench and a top surface of the pillar structure, and wherein the depth of the body region is smaller than the thickness of the gate electrodes, and further wherein the doping concentration of the body region is higher than the doping concentration of the pillar structure; and
a source contact region, formed on the body region and contacting the sidewall of the trench, wherein the source contact region having the first conductivity type and the doping concentration of the source contact region is higher than the doping concentration of the epitaxy layer.

2. The trench gate MOSFET device according to claim 1, wherein the poly-silicon region and the gate electrode are horizontally arranged in the trench.

3. The trench gate MOSFET device according to claim 1, wherein the poly-silicon region is beneath the gate electrode.

4. The trench gate MOSFET device according to claim 1, further comprising a source electrode, contacting the source contact region.

5. The trench gate MOSFET device according to claim 4, wherein the source electrode is further coupled to the poly-silicon region.

6. The trench gate MOSFET device according to claim 4, further comprising a heavy doping region formed in the body region, the heavy doping region having the second conductivity type, the heavy doping region contacting the source electrode, wherein the doping concentration of the heavy doping region is higher than the doping concentration of the body region.

7. The trench gate MOSFET device according to claim 1, wherein the substrate has a voltage applied on, and wherein if the first conductivity type is N-type, the poly-silicon region is coupled to a voltage lower than the voltage applied on the substrate, and wherein if the first conductivity type is P-type, the poly-silicon region is coupled to a voltage higher than the voltage applied on the substrate.

8. The trench gate MOSFET device according to claim 1, wherein the poly-silicon region comprises a plurality of poly-silicon region portions which are separated from each other, and wherein the poly-silicon region portions are vertically arranged in the trench.

9. The trench gate MOSFET device according to claim 1, wherein the pillar structure comprises a plurality of pillar structure portions which are separated from each other, and wherein the pillar structure portions are vertically arranged in the epitaxy layer.

10. A trench gate MOSFET device, comprising a plurality of trench gate MOSFET units, wherein each of the trench gate MOSFET unit comprises:
a substrate, having a first conductivity type;
an epitaxy layer, formed on the substrate, the epitaxy layer having a top surface, wherein the epitaxy layer having the first conductivity type and the doping concentration of the epitaxy layer is lower than the doping concentration of the substrate;
a trench, extending downward from the top surface of the epitaxy layer, wherein the depth of the trench is smaller than the thickness of the epitaxy layer;
an insulation layer, filled into the trench, the insulation layer covering an internal surface of the trench;
a poly-silicon region, formed inside the trench and enclosed by the insulation layer;
a gate electrode, formed in the trench, the gate electrode extending downward from the top surface of the epitaxy, and the gate electrode enclosed by the insulation layer;
a pillar structure, formed in the epitaxy layer, the pillar structure having a second conductivity type;
a body region, formed in the epitaxy layer, the body region having a second conductivity type, wherein the body region contacts a side wall of the trench and a top surface of the pillar structure, and wherein the depth of the body region is smaller than the thickness of the gate electrodes, and further wherein the doping concentration of the body region is higher than the doping concentration of the pillar structure; and
a source contact region, formed on the body region and contacting the sidewall of the trench, wherein the source contact region having the first conductivity type and the doping concentration of the source contact region is higher than the doping concentration of the epitaxy layer.

11. A trench gate MOSFET device, comprising:
a drain region, having a first conductivity type;
a drift region, formed on the drain region, having the first conductivity type;
a trench gate, formed in the drift region, the trench gate comprising a gate electrode and a poly-silicon region, wherein the depth of the trench gate is smaller than the thickness of the drift region;
a super junction pillar, juxtaposing the trench gate, the super junction pillar having a second conductivity type;
a body region, formed on the super junction pillar, the body region having the second conductivity type, wherein the body region contacts a sidewall of the trench gate; and
a source region, formed on the body region, the source region having the first conductivity type.

12. The trench gate MOSFET according to claim 11, wherein the super junction pillar comprises a plurality of super junction pillar portions vertically arranged in the drift region, wherein the super junction pillar portions are separated from each other.
